(19) United States
(12) Patent Application Publication
(10) Pub. No.: US 2026/0096332 A1
(43) Pub. Date: Apr. 2, 2026

(54) DISPLAY PANEL AND DISPLAY DEVICE

(71) Applicant: HKC CORPORATION LIMITED, Shenzhen (CN)

(72) Inventors: Zhi YANG, Shenzhen (CN); Yangling TANG, Shenzhen (CN); Zhisheng XIE, Shenzhen (CN); Qin LIANG, Shenzhen (CN); Xiufeng ZHOU, Shenzhen (CN); Pei XU, Shenzhen (CN)

(21) Appl. No.: 19/331,871

(22) Filed: Sep. 17, 2025

(30) Foreign Application Priority Data
Sep. 30, 2024 (CN) 202411393727.0

(51) Int. Cl. H10K 59/80; H10K 59/122

(52) U.S. Cl. CPC H10K 59/873; H10K 59/122; H10K 59/8722; H10K 59/878

(57) ABSTRACT

A display panel and a display device are disclosed. The display panel includes a substrate, a pixel defining layer, multiple overhang structures, multiple light-emitting elements, an encapsulation layer, a glass adhesive, and an encapsulation cover plate. The pixel defining layer is disposed on the substrate and has multiple openings in a display region. The multiple overhang structures are disposed on the pixel defining layer, surrounding each of the openings. The multiple light-emitting elements are respectively disposed in the multiple openings. The encapsulation layer covers the multiple light-emitting elements and the multiple overhang structures. The glass adhesive is disposed in the non-display region and surrounds the display region. The encapsulation cover plate is disposed on the inorganic encapsulation layer. The encapsulation cover plate is bonded to the substrate via the glass adhesive in the non-display region and is supported by the multiple overhang structures in the display region.

### CROSS-REFERENCE TO RELATED APPLICATIONS

This application claims the priority and benefit of Chinese patent application number 2024113937270, titled “Display Panel and Display Device” and filed Sep. 30, 2024 with China National Intellectual Property Administration, the entire contents of which are incorporated herein by reference.

### TECHNICAL FIELD

The present application relates to the field of display technology, and more particularly relates to a display panel and a display device.

### BACKGROUND

The description provided in this section is intended for the mere purpose of providing background information related to the present application but does not necessarily constitute prior art.

The organic light-emitting diode (OLED) is an organic thin-film electroluminescent device. It has attracted significant attention due to its advantages, including simple manufacturing process, low cost, low power consumption, high brightness, wide viewing angle, high contrast, and the ability to achieve flexible displays. As a new generation display technology, OLED display technology has gradually begun to replace related LCD display technology and will be widely used in electronic devices such as smartphones, computers, full-color televisions, digital cameras, and personal digital assistants. OLED display technology differs from related LCD display technology. The OLED device in the OLED display panel includes an anode, a cathode, and a light-emitting layer disposed between the anode and cathode. When a voltage is applied between the anode and a cathode, holes and electrons move to the light-emitting layer, where they recombine within the light-emitting layer to emit light.

However, the cathode in the OLED display panel is made of an active metal, which is highly sensitive to moisture and oxygen in the air. It is very prone to react with moisture and oxygen that penetrate from the outside, thereby affecting charge injection. Additionally, the moisture and oxygen that penetrate will chemically react with the organic light-emitting material in the light-emitting layer, damaging the organic light-emitting material, significantly reducing its luminous efficiency, and causing a decrease in the performance and lifespan of the OLED display panel. Therefore, the encapsulating requirements for the OLED display panel are very high.

### SUMMARY

It is therefore one purpose of this application to provide a display panel and a display device, which use a glass adhesive and an encapsulation cover plate for encapsulation, preventing moisture and oxygen from entering the display region through the film layer interface, thereby enhancing the encapsulation capability of the display panel.

This application discloses a display panel. The display panel includes a display region and a non-display region. The display panel further includes a substrate, a pixel defining layer, a plurality of overhang structures, a plurality of light-emitting elements, an encapsulation layer, a glass adhesive, and an encapsulation cover plate. The pixel defining layer is disposed on the substrate and has a plurality of openings in the display region. The plurality of overhang structures are disposed on the pixel defining layer and surround each opening. The plurality of light-emitting elements are respectively disposed within the plurality of openings. The encapsulation layer covers the plurality of light-emitting elements and the plurality of overhang structures. The glass adhesive is disposed in the non-display region and surrounds the display region. The encapsulation cover plate is disposed on the encapsulation layer. The encapsulation cover plate is bonded to the substrate in the non-display region by the glass adhesive and is supported by the plurality of overhang structures in the display region.

In some embodiments, the encapsulation layer includes an inorganic encapsulation layer. At each of the openings, a cavity is formed between the inorganic encapsulation layer and the encapsulation cover plate. At each of the overhang structures, the inorganic encapsulation layer is disposed between the overhang structure and the encapsulation cover plate.

In some embodiments, each of the overhang structures includes a first conductive layer and a first insulating layer. The first conductive layer is disposed on the pixel defining layer. The first insulating layer is disposed on the first conductive layer. A width of the first insulating layer is greater than a width of the first conductive layer. Each of the light-emitting elements includes a bottom electrode, a light-emitting layer, and a top electrode. The top electrodes of adjacent light-emitting elements are connected through the corresponding first conductive layer. The light-emitting layers of adjacent light-emitting elements are separated by the corresponding overhang structure. At each of the openings in the display region, a cavity is formed between the corresponding overhang structures and the encapsulation cover plate.

In some embodiments, the light-emitting layer and the top electrode are each formed by full-surface vapor deposition. At the position of the glass adhesive, a light-emitting redundant portion is formed synchronously with the light-emitting layer, and a top electrode redundant portion is formed synchronously with the top electrode. The glass adhesive is used to remove the light-emitting redundant portion and the top electrode redundant portion beneath the glass adhesive position during the laser sintering process.

In some embodiments, the pixel defining layer is formed from an inorganic material. The pixel defining layer extends from the display region to the non-display region, forming an inorganic extension portion in the non-display region. One side of the glass adhesive is in contact with the encapsulation cover plate, and the other side is in contact with the inorganic extension portion.

In some embodiments, the display panel further includes an overhang extension portion. The overhang extension portion further includes a second conductive layer and a second insulating layer. The overhang extension portion is disposed in the non-display region and is located on the side of the glass adhesive that is closer to the display region. On the side of the glass adhesive closer to the display region, the second insulating layer protrudes from the second conductive layer. The overhang extension portion is used to separate each of the light-emitting redundant portion and the top electrode redundant portion.

In some embodiments, the display panel further includes a cathode connection portion. A via hole is also provided in the inorganic extension portion. The cathode connection portion is connected to the second conductive layer through the via hole. The second conductive layer is electrically connected to the first conductive layer of each overhang structure.

In some embodiments, a gap is defined between the overhang extension portion and the glass adhesive. The overhang extension portion surrounds the display region and is formed in the same manufacturing procedure as the plurality of overhang structures in the display region. The first conductive layer of each overhang structure is connected to the second conductive layer.

In some embodiments, the display panel further includes a pixel driving layer. The pixel driving layer is disposed between the substrate and the pixel defining layer. The pixel driving layer further includes a reflective metal layer, which is disposed beneath the glass adhesive and is used to reflect the laser onto the glass adhesive during laser sintering of the glass adhesive.

This application further discloses a display device, including a driving circuit and the above-mentioned display panel, where the driving circuit is used to drive the display panel for display.

The display panel of this application primarily uses a glass adhesive and an encapsulation cover plate for encapsulation. The glass adhesive is arranged to surround the display region. The glass adhesive is used for encapsulation in the non-display region of the display panel, while the encapsulation cover plate in the display region is supported by a plurality of overhang structures. The glass adhesive encapsulation technology used in this application offers better encapsulation reliability compared to the thin film encapsulation technology in exemplary technologies, and avoids the moisture intrusion issues present in the exemplary thin film encapsulation technology. Particularly during high-temperature sintering of the glass adhesive, it can melt and split the full-surface deposited organic material and cathode, thus interrupting the path of moisture and oxygen intrusion, preventing moisture and oxygen from entering the display region through the interface between these layers, which helps enhance the encapsulation capability of the display panel, thus improving its display performance and service life.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a top view schematic diagram of a display panel of this application.

FIG. 2 is a cross-sectional schematic diagram taken along cutting line AA of FIG. 1.

FIG. 3 is a cross-sectional schematic diagram taken along cutting line BB of FIG. 1.

FIG. 4 is a schematic diagram of another cathode connection portion of this application.

FIG. 5 is a schematic diagram of a display device of this application.

In the drawings: 100, display panel; 101, display region; 102, non-display region; 110, substrate; 120, pixel defining layer; 121, opening; 122, inorganic extension portion; 123, via hole; 130, overhang structure; 131, first conductive layer; 132, first insulating layer; 133, overhang extension portion; 134, second conductive layer; 135, second insulating layer; 140, light-emitting element; 141, bottom electrode; 142, light-emitting layer; 143, top electrode; 144, light-emitting redundant portion; 145, top electrode redundant portion; 150, inorganic encapsulation layer; 151, cavity; 160, glass adhesive; 170, encapsulation cover plate; 180, pixel driving layer; 181, cathode connection portion; 182, bottom electrode extension portion; 183, reflective metal layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

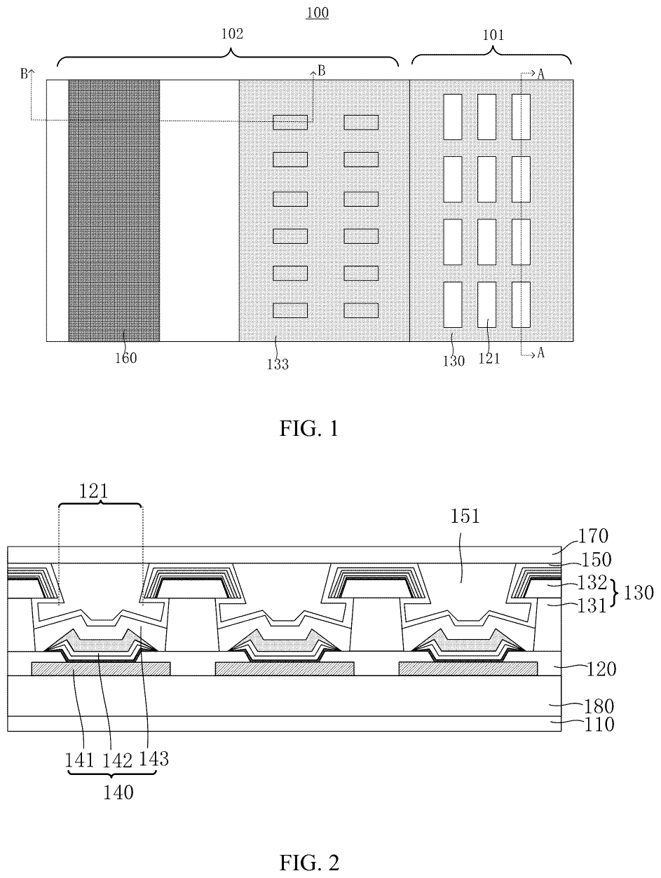

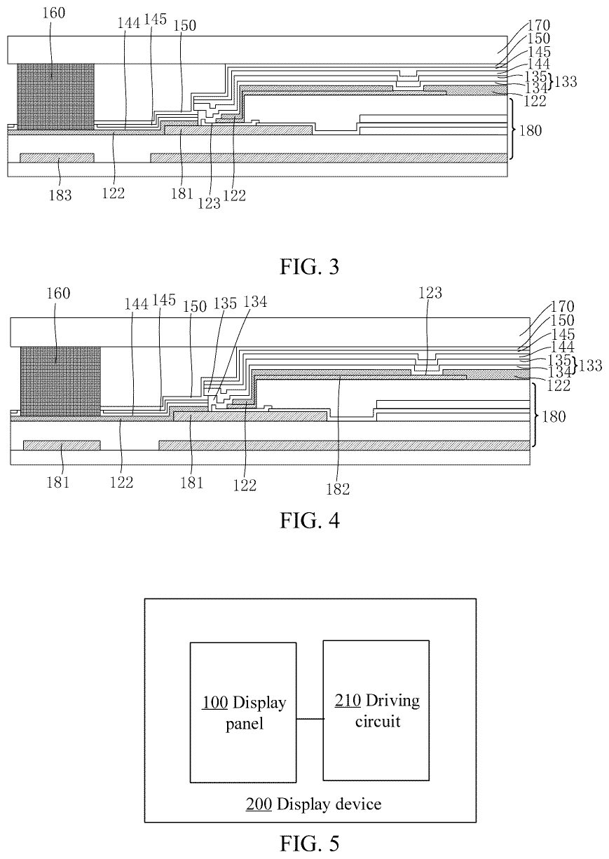

FIG. 1 is a top view schematic diagram of a display panel of this application. FIG. 2 is a cross-sectional schematic diagram taken along cutting line AA of FIG. 1. FIG. 3 is a cross-sectional schematic diagram taken along cutting line BB of FIG. 1. Referring to FIGS. 1-3, this application discloses a display panel 100. The display panel 100 includes a display region 101 and a non-display region 102. The display panel 100 further includes a substrate 110, a pixel defining layer 120, a plurality of overhang structures 130, a plurality of light-emitting elements 140, an encapsulation layer, a glass adhesive 160, and an encapsulation cover plate 170. The pixel defining layer 120 is disposed on the substrate 110, and has a plurality of openings 121 defined in the display region 101. The plurality of overhang structures 130 are disposed on the pixel defining layer 120, surrounding each of the openings 121. The plurality of light-emitting elements 140 are respectively disposed within the plurality of openings 121. The encapsulation layer covers the plurality of light-emitting elements 140 and the plurality of overhang structures 130. The glass adhesive 160 is disposed in the non-display region 102 and surrounds the display region 101. The encapsulation cover plate 170 is disposed on the encapsulation layer. The encapsulation cover plate 170 is bonded to the substrate 110 through the glass adhesive 160 in the non-display region 102, and is supported by the plurality of overhang structures 130 in the display region 101.

The encapsulation of the display panel 100 of this application is primarily achieved using the glass adhesive 160 and the encapsulation cover plate 170, with the glass adhesive 160 surrounding the display region 101. The encapsulation is achieved in the non-display region 102 of the display panel 100 using the glass adhesive 160, while the encapsulation cover plate 170 in the display region 101 is supported by a plurality of overhang structures 130. The glass adhesive encapsulation technology used in this application, compared to the thin film encapsulation technology in exemplary technologies, offers better encapsulation reliability, and avoids the moisture intrusion issues present in the exemplary thin film encapsulation technology. Particularly during high-temperature sintering of the glass adhesive 160, it can melt and split the full-surface vapor-deposited organic material and cathode, thus interrupting the path of moisture and oxygen intrusion, preventing moisture and oxygen from entering the display region 101 through the interface of these layers, which helps enhance the encapsulation capability of the display panel 100, thus improving the display performance and service life of the display panel 100.

The overhang structure 130 is a key structure in maskless vapor deposition technology. That is, during the formation of the plurality of light-emitting elements 140, a metal mask is not required for the vapor deposition process. During the full-surface vapor deposition of the organic light-emitting material, the plurality of overhang structures 130 are used to sever the organic light-emitting material in the corresponding light-emitting element 140 within each opening 121. This ensures that the organic light-emitting material in each light-emitting element 140 is individually arranged, avoiding cross-talk issues. Each light-emitting element 140 includes a bottom electrode 141, a light-emitting layer 142, and a top electrode 143. The light-emitting layer 142 may be formed using an organic light-emitting material, also referred to as the organic light-emitting layer 142, which includes an electron transport layer, a light-emitting layer, and a hole transport layer, etc. These layers are formed using different organic materials. The overhang structure 130 is mainly used to isolate each of the organic light-emitting layer 142 and the top electrode 143.

In the display panel 100 using maskless vapor deposition technology, the organic light-emitting material and the top electrode material in the plurality of light-emitting elements 140 may each be deposited over the entire surface. In particular, no additional manufacturing procedure is used to remove the excess organic light-emitting material and top electrode material in the non-display region 102. Therefore, during subsequent thin-film encapsulation, moisture and oxygen can easily enter the interior of the display panel 100 along the interfaces of these layers, causing damage to the top electrode 143, the bottom electrode 141, and the organic light-emitting layer 142 of the display panel 100, which in turn leads to abnormal light emission in the light-emitting element 140.

Specifically, each of the overhang structures 130 includes a first conductive layer 131 and a first insulating layer 132. The first conductive layer 131 is disposed on the pixel defining layer 120. The first insulating layer 132 is disposed on the first conductive layer 131. Furthermore, the width of the first insulating layer 132 is greater than that of the first conductive layer 131. It is worth mentioning that the widths of the first insulating layer 132 and the first conductive layer 131 referred to here refer to the widths of the first insulating layer 132 and the first conductive layer 131 between two adjacent light-emitting elements 140. When the width of the first insulating layer 132 is greater than that of the first conductive layer 131, the first insulating layer 132 extends beyond both ends of the first conductive layer 131, thereby forming the overhang structure 130. When performing full-surface vapor deposition using organic light-emitting material, at the positions of different openings 121, the overhang structure 130 divides the continuous organic light-emitting material, so that the redundant organic light-emitting material (light-emitting redundant portion 144) vapor-deposited onto the first insulating layer 132 is separated from the organic light-emitting material at the opening 121 location by the overhang structure 130, preventing them from connecting to each other. As a result, when the multiple light-emitting elements 140 emit light independently, the organic light-emitting material of each light-emitting element 140 will not experience electrical crosstalk, thereby avoiding issues with light emission.

Specifically, each of the light-emitting elements 140 includes a bottom electrode 141, a light-emitting layer 142, and a top electrode 143. The top electrodes 143 of adjacent light-emitting elements 140 are connected via the corresponding first conductive layer 131. The light-emitting layers 142 of adjacent light-emitting elements 140 are separated by the corresponding overhang structure 130. Taking an upright top light-emitting element as an example, the bottom electrode 141 of the light-emitting element 140 is the anode, and the top electrode 143 is the cathode. The anode may be formed using a metal material with high reflectance, such as silver. The cathode may be formed using a transparent conductive material, and the cathodes of multiple light-emitting elements 140 are connected to the same driving electrode, having the same driving voltage.

Specifically, the light-emitting layer 142 and the top electrode 143 are formed using full-surface vapor deposition. At the position of the glass adhesive 160, the light-emitting redundant portion 144 is formed synchronously with the light-emitting layer 142, and the top electrode redundant portion 145 is formed synchronously with the top electrode 143. The glass adhesive 160 is used in the laser sintering process to remove the light-emitting redundant portion 144 and the top electrode redundant portion 145 beneath the glass adhesive 160 position.

This application uses the glass adhesive encapsulation technology in the display panel 100 formed using maskless vapor deposition technology, in combination with the encapsulation method by means of the encapsulation cover plate 170.

First, using the glass adhesive 160, the organic light-emitting material and top electrode material beneath the glass adhesive 160 in the non-display region 102 are removed during the laser high-temperature sintering process of the glass adhesive 160. The organic light-emitting material and top electrode material beneath the glass adhesive 160 are directly melted during the laser high-temperature sintering process, while the inorganic material is not melted. The reason is that there is a large difference in the melting points of organic material and inorganic material, with the melting point of inorganic material being higher. By controlling the temperature of the laser sintering process, the organic light-emitting material and cathode material beneath the glass adhesive 160 can be removed. In this embodiment, one side of the glass adhesive 160 directly contacts the inorganic material layer, while the other side directly contacts the encapsulation cover plate 170, forming a encapsulation method by means of a combination of the glass adhesive 160 and the encapsulation cover plate 170. Thus, the moisture barrier capability on the outer side of display panel 100 is superior to the laminated structure of inorganic material layer and organic material layer used in the exemplary thin film encapsulation technique.

Secondly, the encapsulation cover plate 170 is supported by multiple overhang structures 130 inside display panel 100. When using the encapsulation method by the glass adhesive 160 and the encapsulation cover plate 170, additional supporting pillars may be required inside the display panel 100 to support the encapsulation cover plate 170. In this embodiment, multiple overhang structures 130 disposed in the display region 101 can support the encapsulation cover plate 170.

In the display region 101, at each of the openings 121, a cavity 151 may be formed between the overhang structures 130 and the encapsulation cover plate 170. During the formation of the cavity 151, the encapsulation cover plate 170 needs to be attached to the glass adhesive 160 in a vacuum environment, followed by laser sintering of the glass adhesive 160. This ensures that at the position of each overhang structure 130, the encapsulation cover plate 170 is supported by the overhang structure 130, while a cavity 151 is formed at the position of each opening 121. In other words, the multiple overhang structures 130 within the display region 101 of the display panel mainly serve as supports for the encapsulation cover plate 170 above. The formation of cavity 151 helps reduce the compressive pressure between the encapsulation cover plate 170 and the substrate 110, thereby reducing the likelihood of cracking.

The display panel 100 of the present application is suitable for automotive display panels 100 as well as display panels 100 with low flexibility requirements but high waterproof and oxygen barrier demands. Relatively speaking, the automotive display panel 100 has higher waterproof requirements, operates in an environment with higher humidity, and has stricter reliability demands. This embodiment implements the encapsulation of the display panel 100 through the combination of the glass adhesive 160, the encapsulation cover plate 170, and the multiple overhang structures 130, thus achieving a better encapsulation effect.

Continuing to refer to FIG. 2, in the present embodiment, the encapsulation layer mainly protects the cathode of the light-emitting element 140. When the material of the cathode is indium tin oxide (ITO) or indium zinc oxide (IZO), the cathode material and organic light-emitting material are easily corroded by moisture and oxygen, which can cause the light-emitting element 140 to fail. The encapsulation layer of the present embodiment is mainly provided to protect the plurality of light-emitting elements 140, and can be made of an inorganic material. The inorganic material includes one or more of silicon nitride, silicon oxide, or silicon oxynitride, thereby forming an encapsulation layer. After forming the encapsulation layer and forming the glass adhesive 160 around the periphery, the encapsulation cover plate 170 is formed on the encapsulation layer. In contrast to thin film encapsulation, this embodiment only forms a single inorganic encapsulation layer 150, without the need to form a subsequent organic encapsulation layer and multiple stacked layers. On the one hand, this reduces the processing steps, and on the other hand, it alleviates the issue of process complexity introduced by the manufacturing procedure of the organic encapsulation layer.

Specifically, the encapsulation layer includes an inorganic encapsulation layer 150. At each of the openings 121, a cavity 151 is formed between the inorganic encapsulation layer 150 and the encapsulation cover plate 170. At each of the overhang structures 130, the inorganic encapsulation layer 150 is disposed between the overhang structure 130 and the encapsulation cover plate 170.

The inorganic encapsulation layer 150 in the present application covers the multiple light-emitting elements 140 and the multiple overhang structures 130, and extends from the display region 101 to the non-display region 102. The inorganic encapsulation layer 150 needs to be removed in the region where the glass adhesive 160 is formed to prevent incomplete removal during the subsequent process of removing the organic light-emitting material and cathode material, which could lead to residue issues. In this embodiment, the first insulating layer 132 may be formed from one or more materials selected from silicon oxide, silicon nitride, or silicon oxynitride. The inorganic encapsulation layer 150 is further disposed between the multiple overhang structures 130 and the encapsulation cover plate. The inorganic encapsulation layer 150 may be formed from silicon nitride material, ensuring better contact between the multiple overhang structures 130 and the encapsulation cover plate through the inorganic encapsulation layer 150, thus reducing the likelihood of issues such as cracking of the inorganic encapsulation layer 150.

It is worth mentioning that the sealing method using the glass adhesive 160 and the encapsulation cover plate 170 in this application also solves the leveling issue of the organic encapsulation layer in thin-film encapsulation in maskless vapor deposition technology. Specifically, when the light-emitting element 140 uses maskless vapor deposition technology, the pixel defining layer 120 may be formed of an inorganic material, and when the pixel defining layer 120 is made of an inorganic material, it may be thin, for example, 0.1 μm or less. The barrier dam located in the non-display region 102 of the display panel 100 may be mainly composed of the pixel defining layer 120 and a planarization layer stacked beneath the pixel defining layer 120. Therefore, during the subsequent leveling process of the organic encapsulation layer, due to the thin thickness of the pixel defining layer 120, even with the planarization layer disposed below the pixel defining layer 120, it is difficult to prevent the organic encapsulation layer from overflowing, which leads to the failure of the organic encapsulation layer. When the organic encapsulation layer overflows, and at the same time, due to the full-surface vapor deposition of the organic light-emitting material in the non-display region 102, there may be redundant areas of organic light-emitting material, which increases the risk of moisture and oxygen invasion.

In this embodiment, after removing the organic encapsulation layer, the risk of overflow during the leveling of the organic encapsulation layer is eliminated, so there is no need to form a blocking dam at the leveling blocking location, thereby reducing the procedures of organic encapsulation and secondary inorganic encapsulation in the film encapsulation. It can be understood that in this embodiment, the encapsulation layer is the inorganic encapsulation layer 150, which can be formed using the manufacturing procedure of the first inorganic encapsulation in thin film encapsulation technology. The inorganic encapsulation layer 150 covers the multiple light-emitting elements 140 and the multiple overhang structures 130, thereby providing effective encapsulation.

Specifically, the glass adhesive 160 is arranged in an annular shape, surrounding the display region 101. The glass adhesive 160 may also be referred to as a sealant frame that is disposed at the outermost position of the non-display region 102, and its projection on the substrate 110 may be “track-shaped” or a rounded rectangle. One side of the glass adhesive 160 is bonded to the encapsulation cover plate 170, and the other side is bonded to the substrate 110. Of course, there are specific layers disposed on the substrate 110, and so the bonding is actually with the layer(s) disposed on the substrate 110.

Specifically, the display panel 100 may further include a pixel driving layer 180, which is disposed on the substrate 110. The pixel driving layer 180 may include multiple metal layers and multiple insulating layers. By using multiple metal layers and multiple insulating layers, thin-film transistor devices, data driving lines, etc. are formed, thereby creating a driving circuit that enables individual control of each light-emitting element 140.

Specifically, the pixel driving layer 180 is disposed between the substrate 110 and the pixel defining layer 120. The pixel driving layer 180 further includes a reflective metal layer 183, which is disposed beneath the glass adhesive 160 to reflect the laser onto the glass adhesive 160 during the laser sintering process.

In this embodiment, a reflective metal layer 183 is disposed beneath the glass adhesive 160 in the pixel driving layer 180. The primary function of the reflective metal layer 183 is to reflect the laser during the laser sintering process of the glass adhesive 160, concentrating the heat on the glass adhesive 160. This allows the glass adhesive 160 to sinter and bond the cover plate 170 and the pixel driving layer 180 together, thereby encapsulating the cover plate 170 and the pixel driving layer 180. The reflective metal layer 183 may be synchronously formed with the metal layers in the pixel driving layer 180 that are used to form the thin-film transistors, scan lines, or data lines, using the same material.

It can be understood that during the formation of the organic light-emitting layer 142 and the cathode, since the full-surface vapor deposition technique is used, there are the light-emitting redundant portion 144 and the top electrode redundant portion 145 between the glass adhesive 160 and the pixel driving layer 180 before the glass adhesive 160 undergoes laser high-temperature sintering. At this point, there is no need to etch and remove the light-emitting redundant portion 144 and the top electrode redundant portion 145 below the glass adhesive 160. During the laser sintering process, the organic light-emitting material of the light-emitting redundant portion 144 and the cathode material of the top electrode redundant portion 145 are directly melted, so that the light-emitting redundant portion 144 and the top electrode redundant portion 145 are melted and split at the location of the glass adhesive 160. As a result, the light-emitting redundant portion 144 outside the glass adhesive 160 is no longer connected to the light-emitting redundant portion 144 inside the glass adhesive 160, and the top electrode redundant portion 145 outside the glass adhesive 160 is also no longer connected to the top electrode redundant portion 145 inside the glass adhesive 160.

Specifically, the pixel defining layer 120 is formed using an inorganic material. The pixel defining layer 120 extends from the display region 101 to the non-display region 102, forming an inorganic extension portion 122 in the non-display region 102. One side of the glass adhesive 160 is in contact with the encapsulation cover plate 170, and the other side of the glass adhesive 160 is in contact with the inorganic extension portion 122.

In this embodiment, the pixel defining layer 120 also extends below the glass adhesive 160, forming an inorganic extension portion 122 that extends into the non-display region 102. Considering that a passivation layer may be disposed above the pixel driving layer 180, and the passivation layer may be formed using an organic material, it is easy to melt the planarization layer on the pixel driving layer 180 during the laser sintering of the organic light-emitting material and the cathode material. Therefore, in this embodiment, the inorganic extension portion 122 formed by an inorganic material is used to isolate the glass adhesive 160 from the passivation layer. The reflective metal layer 183 is disposed beneath the passivation layer and below the glass adhesive 160, its projection on the substrate 110 coinciding with the projection of the glass adhesive 160 on the substrate 110.

Considering that at the position of the glass adhesive 160, only the inorganic extension portion 122 is disposed on the pixel driving layer 180, and it is not possible to route the cathode wiring to the binding connections of the display panel 100, the cathode may be connected to the pixel driving layer 180, with the cathode signal provided by an external circuit board.

Specifically, the display panel 100 further includes a cathode connection portion 181. The inorganic extension portion 122 further has a plurality of via holes 123. The cathode connection portion 181 is connected to the first conductive layer 131 of each overhang structure 130 through the via holes 123. The first conductive layer 131 is connected to the respective cathode.

In this embodiment, the first conductive layer 131, which connects to the cathode, is connected to the cathode connection portion 181 through the via hole 123. The cathode connection portion 181 is disposed within the pixel driving layer 180 and is formed using a metal layer or conductive layer within the pixel driving layer 180. Via holes 123 are formed in the inorganic extension portion 122. This allows the first conductive layer 131 of each overhang structure 130 to be connected through the via holes to the cathode connection portion 181 in the pixel driving layer 180, enabling the driving of the cathodes.

Of course, in order to prevent moisture from extending from the organic light-emitting material and the cathode material into the display region 101, this embodiment also utilizes the overhang extension portion 133 disposed in the non-display region 102 to block it.

Specifically, the display panel 100 further includes an overhang extension portion 133. The overhang extension portion 133 further includes a second conductive layer 134 and a second insulating layer 135. The overhang extension portion 133 is disposed in the non-display region 102 and located on the side of the glass adhesive 160 adjacent to the display region 101. On the side of the glass adhesive 160 near the display region 101, the second insulating layer 135 extends beyond the second conductive layer 134. The overhang extension portion 133 is used to separately isolate each of the light-emitting redundant portion 144 and the top electrode redundant portion 145. Specifically, a gap is defined between the overhang extension portion 133 and the glass adhesive 160.

In this embodiment, the overhang extension portion 133 surrounds the display region 101 and is formed in the same manufacturing procedure as the plurality of overhang structures 130 in the display region 101. The first conductive layer 131 of each of the overhang structures is connected to the second conductive layer 134. In addition to supporting the encapsulation cover plate 170, the overhang extension portion 133 also serves to divide each of the light-emitting redundant portion 144 and the top electrode redundant portion 145 in the non-display region 102. Specifically, at the edge of the overhang extension portion 133, both sides of the light-emitting redundant portion 144 are disconnected, and both sides of the top electrode redundant portion 145 are disconnected, thus preventing moisture from transferring between them.

FIG. 4 is a schematic diagram of another cathode connection portion in the present application. Referring to FIG. 4, considering the limited wiring space in the non-display region 102 near the display region 101 (as illustrated in FIG. 1), the second conductive layer 134 may also be used for connection. Specifically, the cathode connection portion 181 is connected to the second conductive layer 134 through the via hole 123, the second conductive layer 134 is connected to the first conductive layer 131 of each overhang structure 130, and the first conductive layer 131 is connected to the respective cathode.

In this embodiment, the cathode is connected to the cathode connection portion 181 in the pixel driving layer 180 through the first conductive layer 131, the second conductive layer 134, and the via holes 123 located beneath the overhang extension portion 133, without using the layout space of the display region 101 or the non-display region 102 near the display region 101.

In another embodiment, after forming the via holes 123 in the inorganic extension portion 122, the bottom electrode 141 may be formed in the same layer manufacturing procedure to create the bottom electrode extension portion 182, which transmits the signal to the cathode connection portion 181.

FIG. 5 is a schematic diagram of a display device according to the present application. Referring to FIG. 5, the present application further discloses a display device. The display device 200 includes a driving circuit 210 and any one of the display panels 100 described above. The driving circuit 210 is used to drive the display panel 100 for display.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling within the scope of protection of the present application.

What is claimed is:

1. A display panel, comprising a display region and a non-display region, the display panel further comprising:
a substrate;
a pixel defining layer, disposed on the substrate, the pixel defining layer having a plurality of openings in the display region;
a plurality of overhang structures, disposed on the pixel defining layer and surrounding each of the plurality of openings;
a plurality of light-emitting elements, respectively disposed in the plurality of openings;
an encapsulation layer, covering the plurality of light-emitting elements and the plurality of overhang structures;
a glass adhesive, disposed in the non-display region and surrounding the display region; and
an encapsulation cover plate, disposed on the encapsulation layer, the encapsulation cover plate being bonded to the substrate in the non-display region by the glass adhesive and being supported by the plurality of overhang structures in the display region.

2. The display panel as recited in claim 1, wherein the encapsulation layer comprises an inorganic encapsulation layer;
wherein at each of the plurality of openings, there is formed a cavity between the inorganic encapsulation layer and the encapsulation cover plate;
wherein at each of the plurality of overhang structures, the inorganic encapsulation layer is disposed between the overhang structure and the encapsulation cover plate.

3. The display panel as recited in claim 1, wherein each of the plurality of overhang structures comprises a first conductive layer and a first insulating layer; wherein the first conductive layer is disposed on the pixel defining layer, and the first insulating layer is disposed on the conductive layer; and wherein a width of the first insulating layer is greater than a width of the first conductive layer.

4. The display panel as recited in claim 3, wherein each of the plurality of light-emitting elements comprises a bottom electrode, a light-emitting layer, and a top electrode;
wherein the top electrodes of adjacent light-emitting elements are connected by a corresponding first conductive layer;
wherein the light-emitting layers of adjacent light-emitting elements are separated by a corresponding overhang structure.

5. The display panel as recited in claim 4, wherein at each of the plurality of openings in the display region, there is formed a cavity between the corresponding overhang structures and the encapsulation cover plate.

6. The display panel as recited in claim 5, wherein the light-emitting layer and the top electrode are each formed by full-surface vapor deposition;
wherein at a position of the glass adhesive, a light-emitting redundant portion is formed synchronously with the light-emitting layer, and a top electrode redundant portion is formed synchronously with the top electrode;
wherein the glass adhesive is configured to remove the light-emitting redundant portion and the top electrode redundant portion below the glass adhesive during a laser sintering process.

7. The display panel as recited in claim 6, wherein the pixel defining layer is formed of an inorganic material and extends from the display region to the non-display region thus forming an inorganic extension portion in the non-display region;
wherein one side of the glass adhesive is in contact with the encapsulation cover plate, and wherein another side of the glass adhesive is in contact with the inorganic extension portion.

8. The display panel as recited in claim 7, further comprising an overhang extension portion, the overhang extension portion comprising a second conductive layer and a second insulating layer; wherein the overhang extension portion is arranged in the non-display region and disposed on a side of the glass adhesive facing towards the display region;
wherein on the side of the glass adhesive facing towards the display region, the second insulating layer protrudes from the second conductive layer;
wherein the overhang extension portion is configured to disconnect each of the light-emitting redundant portion and the top electrode redundant portion.

9. The display panel as recited in claim 8, further comprising a cathode connection portion;
wherein the inorganic extension portion further comprises at least one via hole, wherein the cathode connection portion is connected to the second conductive layer through the at least one via hole, wherein the second conductive layer is electrically connected to the first conductive layer of each of the plurality of overhang structures.

10. The display panel as recited in claim 8, wherein there is defined a gap between the overhang extension portion and the glass adhesive;
wherein the overhang extension portion surrounds the display region and is formed in a same manufacturing procedure as the plurality of overhang structures in the display region;
wherein the first conductive layer of each of the plurality of overhang structures is connected to the second conductive layer.

11. The display panel as recited in claim 1, further comprising a pixel driving layer arranged between the substrate and the pixel defining layer;
wherein the pixel driving layer further comprises a reflective metal layer, which is arranged beneath the glass adhesive and is configured to reflect laser onto the glass adhesive during laser sintering of the glass adhesive.

12. A display device, comprising a driving circuit and a display panel, wherein the driving circuit is configured to drive the display panel for display; wherein the display panel comprises a display region and a non-display region, the display panel further comprising:
a substrate;
a pixel defining layer, disposed on the substrate, the pixel defining layer having a plurality of openings in the display region;
a plurality of overhang structures, disposed on the pixel defining layer and surrounding each of the plurality of openings;
a plurality of light-emitting elements, respectively disposed in the plurality of openings;
an encapsulation layer, covering the plurality of light-emitting elements and the plurality of overhang structures;
a glass adhesive, disposed in the non-display region and surrounding the display region; and
an encapsulation cover plate, disposed on the encapsulation layer, the encapsulation cover plate being bonded to the substrate in the non-display region by the glass adhesive and being supported by the plurality of overhang structures in the display region.

13. The display device as recited in claim 12, wherein the encapsulation layer comprises an inorganic encapsulation layer;
wherein at each of the plurality of openings, there is formed a cavity between the inorganic encapsulation layer and the encapsulation cover plate;
wherein at each of the plurality of overhang structures, the inorganic encapsulation layer is disposed between the overhang structure and the encapsulation cover plate.

14. The display device as recited in claim 12, wherein each of the plurality of overhang structures comprises a first conductive layer and a first insulating layer; wherein the first conductive layer is disposed on the pixel defining layer, and the first insulating layer is disposed on the conductive layer; wherein a width of the first insulating layer is greater than a width of the first conductive layer;
wherein each of the plurality of light-emitting elements comprises a bottom electrode, a light-emitting layer, and a top electrode; wherein the top electrodes of adjacent light-emitting elements are connected by a respective first conductive layer;
wherein the light-emitting layers of adjacent light-emitting elements are separated by a respective overhang structure, wherein at each of the plurality of openings in the display region, there is formed a cavity between the corresponding overhang structures and the encapsulation cover plate.

15. The display device as recited in claim 14, wherein the light-emitting layer and the top electrode are each formed by full-surface vapor deposition;
wherein at a position of the glass adhesive, a light-emitting redundant portion is formed synchronously with the light-emitting layer, and a top electrode redundant portion is formed synchronously with the top electrode;
wherein the glass adhesive is configured to remove the light-emitting redundant portion and the top electrode redundant portion below the glass adhesive position during a laser sintering process.

16. The display device as recited in claim 15, wherein the pixel defining layer is formed of an inorganic material and extends from the display region to the non-display region thus forming an inorganic extension portion in the non-display region;
wherein one side of the glass adhesive is in contact with the encapsulation cover plate, and wherein another side of the glass adhesive is in contact with the inorganic extension portion.

17. The display device as recited in claim 16, wherein the display panel further comprises an overhang extension portion, the overhang extension portion comprising a second conductive layer and a second insulating layer; wherein the overhang extension portion is arranged in the non-display region and disposed on a side of the glass adhesive facing towards the display region,
wherein on the side of the glass adhesive facing towards the display region, the second insulating layer protrudes from the second conductive layer;
wherein the overhang extension portion is configured to disconnect each of the light-emitting redundant portion and the top electrode redundant portion.

18. The display device as recited in claim 17, wherein the display panel further comprises a cathode connection portion, wherein the inorganic extension portion further comprises at least one via hole, wherein the cathode connection portion is connected to the second conductive layer through the at least one via hole, wherein the second conductive layer is electrically connected to the first conductive layer of each of the plurality of overhang structures.

19. The display device as recited in claim 17, wherein there is defined a gap between the overhang extension portion and the glass adhesive;
wherein the overhang extension portion surrounds the display region and is formed in a same manufacturing procedure as the plurality of overhang structures in the display region;
wherein the first conductive layer of each of the plurality of overhang structures is connected to the second conductive layer.

20. The display device as recited in claim 12, wherein the display panel further comprises a pixel driving layer arranged between the substrate and the pixel defining layer;
wherein the pixel driving layer further comprises a reflective metal layer, which is arranged beneath the glass adhesive and is configured to reflect laser onto the glass adhesive during laser sintering of the glass adhesive.
